(19) United States
(12) Patent Application Publication
(10) Pub. No.: US 2007/0114565 A1
(43) Pub. Date: May 24, 2007

(54) Integrated field-effect transistor-thyristor device

(76) Inventor: Udaysimha Alasinger Makaram, Bangalore (IN)

Correspondence Address: Ryan, Mason & Lewis, LLP, 90 Forest Avenue, Locust Valley, NY, 11560, US

(21) Appl. No.: 11/285,801

(22) Filed: Nov. 23, 2005

(51) Int. Cl. H01L 29/74

(52) U.S. Cl. 257/133

(57) ABSTRACT

An integrated FET-thyristor device includes a semiconductor substrate of a first conductivity type, a first semiconductor region of a second conductivity type formed in the substrate proximate an upper surface of the substrate, and a second semiconductor region of the second conductivity type formed in the substrate proximate a bottom surface of the substrate. The second semiconductor region is substantially vertically aligned with and spaced apart from the first semiconductor region. A third semiconductor region of the first conductivity type is formed in a portion of the first semiconductor region proximate the upper surface of the substrate. At least one gate region of the second conductivity type is formed on a sidewall of the substrate and substantially surrounding at least a portion of each of the first, second and third semiconductor regions.

### FIELD OF THE INVENTION

The present invention relates generally to electronic devices, and more particularly relates to power switching devices.

### BACKGROUND OF THE INVENTION

Power switching applications, including, for example, power rectification and control, generally involve the use of electronic devices and/or circuits configured for turning on and turning off large voltages, which may several hundred volts, or large currents, which may be on the order of tens of amperes. In certain high-speed power switching applications, it may necessary to turn on and turn off such large voltages or currents in a relatively short period of time, such as, for example, in a few microseconds.

It is well known to employ thyristors, such as, for example, silicon-controlled rectifiers (SCRs), as an economical and efficient means of switching large voltages or currents. A conventional SCR includes an anode, a cathode and a gate electrode. In a forward-bias region, wherein the anode is positive with respect to the cathode, the SCR has two distinct operating states. As the forward bias is initially increased from zero volts, the SCR allows only a small forward current and exhibits high forward resistance. This region of operation is often referred to as the forward blocking region, or “off” state. As the forward bias is further increased, the off-state current increases very slowly until a breakover voltage (V_{BO}) of the device is reached. At the breakover voltage, the SCR suddenly switches to a high conductance region, or “on” state, wherein the anode current is limited primarily by the resistance of an external circuit to which the SCR is connected. The breakover voltage of the SCR can be varied by applying a signal of a certain character to the gate electrode, causing the SCR to switch from the off state to the on state at a lower forward bias. Normally, the SCR is operated well below the breakover voltage and is then made to switch on by a gate signal of sufficient amplitude. This assures that the SCR turns on at precisely the right instant. Turning off the SCR at a precise instant, however, is considerably more difficult, particularly when switching large currents.

As previously explained, an SCR functions as a controlled switch which is triggered by an external control signal applied to the gate electrode. The SCR is basically a latching device. Thus, once the SCR begins conducting, the gate electrode of the SCR essentially no longer controls the SCR, and anode current continues to flow in spite of the gate signal that may be applied to the SCR. In order to turn off the SCR, special commutation circuitry must be added. However, such commutation circuitry is often complex and slow, and thus is not well-suited for a high-speed power switching application.

Accordingly, there exists a need for an improved electronic device suitable for use in a high-speed power switching application that does not suffer from one or more of the problems exhibited by conventional devices.

### SUMMARY OF THE INVENTION

The present invention meets the above-noted need by providing, in an illustrative embodiment, a single integrated electronic device which combines the beneficial properties of a field-effect transistor (FET) and a thyristor (e.g., an SCR) to thereby form a FET-thyristor device operative to quickly (e.g., less than about a few microseconds) turn on and turn off substantially large currents (e.g., tens of amperes or more). Moreover, the FET-thyristor device of the present invention eliminates the need for complex commutation circuitry which adds significant cost to conventional high-speed power switching methodologies.

In accordance with one aspect of the invention, an integrated FET-thyristor device includes a semiconductor substrate of a first conductivity type, a first semiconductor region of a second conductivity type formed in the substrate proximate an upper surface of the substrate, and a second semiconductor region of the second conductivity type formed in the substrate proximate a bottom surface of the substrate. The second semiconductor region is substantially vertically aligned with and spaced apart from the first semiconductor region. A third semiconductor region of the first conductivity type is formed in a portion of the first semiconductor region proximate the upper surface of the substrate. At least one gate region of the second conductivity type is formed on a sidewall of the substrate and substantially surrounding at least a portion of each of the first, second and third semiconductor regions.

In accordance with a second aspect of the invention, an integrated FET-thyristor device includes a semiconductor substrate having a plurality of differently doped layers. The plurality of differently doped layers includes a multiple-layer sequence including a first doped layer of a first conductivity type, a second doped layer of a second conductivity type formed laterally adjacent to the first doped layer, a third doped layer of the first conductivity type formed laterally adjacent to the second doped layer, and a fourth doped layer of the second conductivity type formed laterally adjacent to the third doped layer. The FET-thyristor device further includes one or more gate regions of the first conductivity type formed on an upper surface and a bottom surface of the semiconductor substrate, vertically adjacent to the second doped layer and electrically isolated from the first and third doped layers. A first gate contact provides electrical connection to the third doped layer, and one or more second gate contacts provide electrical connection to the respective one or more gate regions.

In accordance with a third aspect of the invention, a method of forming an integrated FET-thyristor device includes the steps of forming a first semiconductor region of a first conductivity type formed in a semiconductor substrate of a second conductivity type proximate an upper surface of the substrate, forming a second semiconductor region of the first conductivity type in the substrate proximate a bottom surface of the substrate, the second semiconductor region being substantially vertically aligned with and spaced apart from the first semiconductor region, forming a third semiconductor region of the second conductivity type in a portion of the first semiconductor region proximate the upper surface of the substrate, and forming at least one gate region of the first conductivity type on a sidewall of the substrate substantially surrounding at least a portion of each of the first, second and third semiconductor regions.

These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 is a diagram depicting a standard FET device and corresponding bias sources for biasing the FET device in a particular region of operation.

FIG. 2 is a diagram depicting a standard SCR device and corresponding bias source.

FIG. 3 is a diagram depicting an exemplary FET-thyristor device and associated bias circuitry, formed in accordance with one embodiment of the present invention.

FIGS. 4-7 are diagrams depicting steps in an illustrative methodology which may be used in forming a FET-thyristor device of the type shown in FIG. 3, in accordance with one aspect of the present invention.

### DETAILED DESCRIPTION OF THE INVENTION

The present invention will be described herein in the context of an illustrative dual gate FET-thyristor device suitable for use, for example, in a high-speed power switching application. It should be understood, however, that the present invention is not limited to the particular FET-thyristor device arrangement shown. Rather, the invention is more generally applicable to techniques for advantageously combining the beneficial properties of a FET and a thyristor (e.g., an SCR) in a single integrated semiconductor structure. Although implementations of the present invention are described herein with specific reference to a metal-oxide-semiconductor (MOS) fabrication process, it is to be understood that the invention is not limited to such a fabrication process, and that other suitable fabrication processes (e.g., bipolar, etc.), may be similarly employed, as will become apparent to those skilled in the art.

It is to be understood that the various layers and/or regions shown in the accompanying figures may not be drawn to scale. Furthermore, one or more semiconductor layers of a type commonly used in such integrated circuit structures may not be explicitly shown in a given figure for ease of explanation. This does not imply that the semiconductor layers not explicitly shown are omitted in the actual integrated circuit device. In the figures, like reference numerals designate identical or corresponding elements throughout the several views.

FIG. 1 depicts, schematically and in cross section, an illustrative FET circuit 100 comprising a FET device 102 connected to bias sources 114 and 116, generating bias voltages, Vgg and Vdd, respectively, for biasing the FET device in a desired region of operation. As apparent from the figure, the FET device 102 may be viewed conceptually as a P-type semiconductor wafer 108 having a source (S) 104, connected to a source electrode, and a drain (D) 106, connected to a drain electrode. The source and drain 104, 106 are formed at laterally opposite ends of the P-type wafer 108 and are electrically separate from one another. During normal operation of the FET device 102, a negative (−) terminal of bias source 116 may be connected to the source region 104 and a positive (+) terminal of 116 may be connected to the drain region 106. Electrons supplied at the source 104 will travel to the drain 106, and will establish a drain current, Id, in the FET device 102.

Two N-type gate (G) regions 110 are formed between the source and drain regions of the P-type wafer 108, such as, for example, proximate a middle portion of the P-type wafer as shown. A positive (+) terminal of bias source 114 is connected to the gate regions 110 and a negative (−) terminal of 114 is connected to the source 104 to thereby reverse bias a P-N junction formed between the P-type wafer 108 and the N-type gate regions 110. Since the bias voltage Vgg is applied to the gate regions of the FET device, Vgg is generally referred to as the gate voltage. In accordance with known FET principles of operation, depletion regions 112 will be created in the P-type wafer 108, proximate the N-type gate regions 110, whose depth will be a function of the bias voltage Vgg. Between the two depletion regions 112 a channel is formed in the P-type wafer 108 having a width, W, which is proportional to the depth of the depletion regions. The deeper the depletion regions are, the smaller the channel width will be, and vice versa.

The drain current Id in the FET device 102 may be controlled primarily as a function of the channel width. By varying the bias voltage Vgg, the channel width can be varied accordingly, and thus the drain current Id can be varied. As the bias voltage Vgg applied to the FET device 102 is increased, the channel will eventually become cut off in the sense that there will be no charge carriers available and the channel essentially becomes a nonconductor (e.g., channel width is substantially zero). The voltage Vgg at which channel cutoff occurs is often referred to as the “pinch-off” voltage, Vp, of the FET device.

A second mechanism which affects drain current in the FET device 102 is the magnitude of the bias voltage Vdd applied across the channel itself. With bias source 116 connected in the manner shown, Vdd produces a voltage gradient along the channel, with the side of the channel closest the drain 106 being more positive with respect to the side of the channel closest to the source 104. Because of this voltage gradient, the depletion regions 112 will generally vary in width along the channel. When Vdd is increased, drain current Id increases substantially linearly. The voltage gradient along the channel becomes steeper and the depletion regions 112 increase in depth to the point where they eventually touch at one end of the channel. This condition is often referred to as channel “pinch-off.” Channel pinch-off generally occurs at the side of the channel nearest the drain (e.g., positive) region, and only when the bias voltage Vdd across the channel is sufficiently large and substantially equal to the pinch-off voltage Vp of the device.

It is to be understood that the FET device, during normal operation, functions predominantly as an amplifier. Accordingly, a relatively small variation in the gate voltage Vgg is able to generate a significantly larger variation in drain current Id. The amount of variation in the drain current Id relative to a variation in the gate voltage Vgg will be primarily a function of a gain of the FET device.

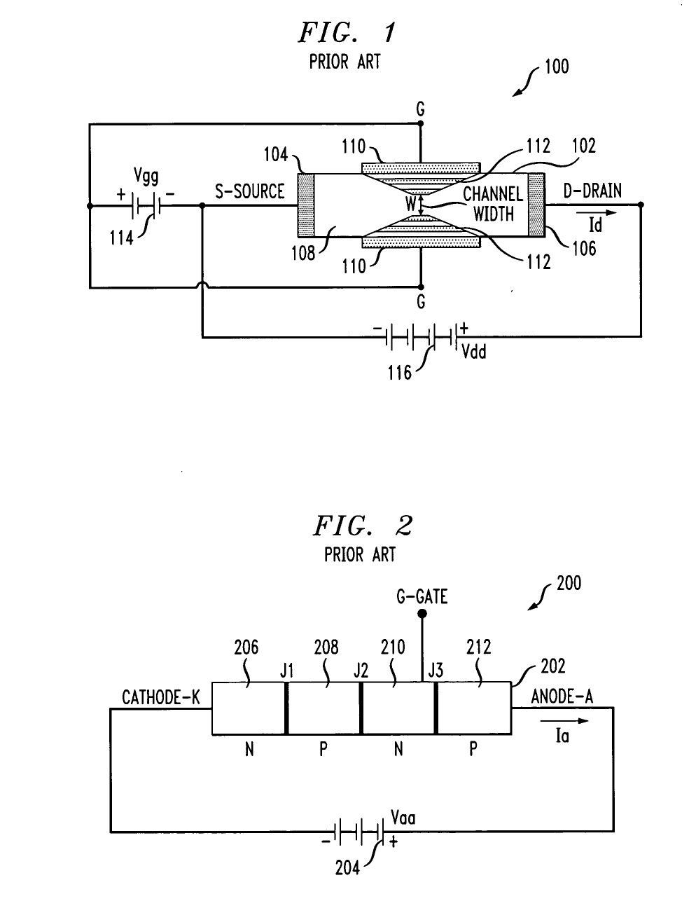

FIG. 2 is a diagram depicting an illustrative SCR circuit 200 including a standard SCR device 202 connected to a bias source 204 supplying a bias voltage, Vaa. The SCR 202, which is shown in cross section, consists of four layers of semiconductor material, namely, two N-type semiconductor layers and two P-type semiconductor layers, arranged in an alternating fashion as shown. Specifically, a first N-type semiconductor layer 206, which forms a cathode (K) of the SCR, is formed adjacent to a first P-type semiconductor layer 208. A second P-type semiconductor layer 212, which forms an anode (A) of the SCR, is formed adjacent to a second N-type semiconductor layer 210, the first P-type semiconductor layer 208 being sandwiched between and adjacent to the first and second N-type semiconductor layers 206 and 210, respectively. With the N-type and P-type semiconductor layers arranged in this manner, three P-N junctions are formed in the SCR, namely, junction J1, formed between P-type semiconductor layer 208 and N-type semiconductor layer 206, junction J2, formed between P-type semiconductor layer 208 and N-type semiconductor layer 210, and junction J3, formed between P-type semiconductor layer 212 and N-type semiconductor layer 210. The SCR 202 further includes a control gate (G) connected to N-type semiconductor layer 210, proximate junction J3. The control gate may be used to trigger the SCR, as will be explained below.

With the bias source 204 connected in the manner shown, namely, with a negative (−) terminal of the bias source connected to the cathode 206 and a positive (+) terminal of the bias source connected to the anode 212, junctions J1 and J3 will become forward-biased and junction J2 will become reverse-biased when the voltage Vaa of sufficient amplitude is applied across the SCR device 202. With junction J2 reverse-biased, substantially no current, other than perhaps a slight leakage current, will flow through the SCR from the cathode to the anode. By applying a positive voltage to the control gate, holes will be injected into the N-type semiconductor layer 210 adjoining junction J3. When the number of holes, which are minority carriers in the N-type material, overwhelms the number of electrons, which are majority carriers in the N-type material, the N-type semiconductor layer 210 will effectively behave as a P-type layer, thus forming an N—P—P—P layer device which is forward-biased. An anode current, Ia, will flow through the SCR device 202 at this point which is limited primarily by an on-resistance of the SCR and a resistance of an external circuit to which the SCR is connected.

As previously explained, however, since the SCR is a latching device, once the SCR begins conducting current, an external commutation circuit is generally required to turn off the device. The use of complex commutation circuits, however, adds cost to a circuit (e.g., power switching circuit) employing the SCR and is therefore undesirable. Moreover, such commutation circuits are typically not able to quickly turn off the SCR (e.g., within a few microseconds) and are therefore not well-suited in a high-speed power switching application.

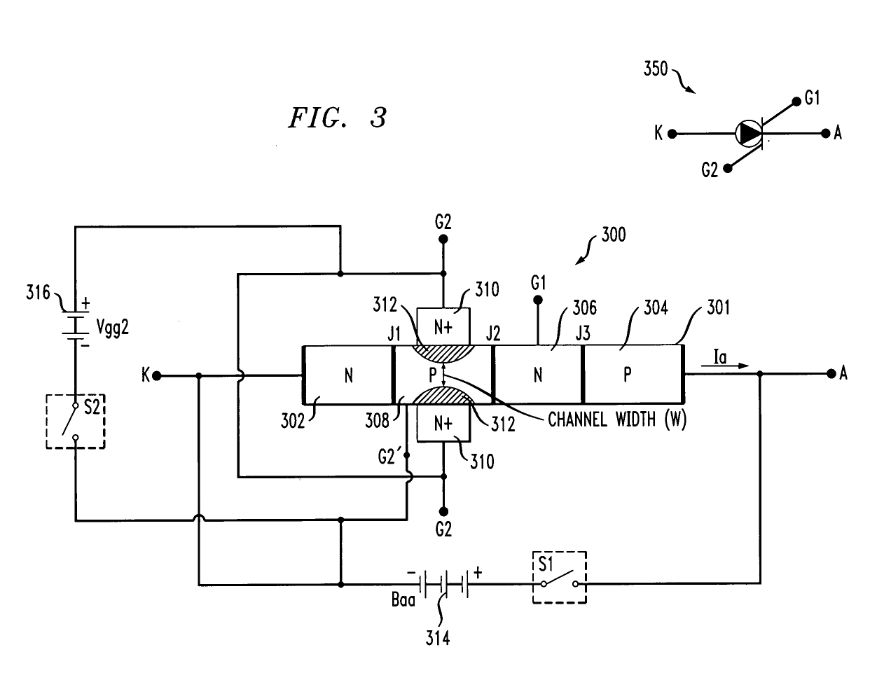

FIG. 3 is a diagram depicting an exemplary FET-thyristor device 300, formed in accordance with one embodiment of the present invention. A corresponding schematic symbol 350 for the FET-thyristor device 300 is also shown. FET-thyristor device 300 combines the beneficial characteristics of a thyristor (e.g., an SCR, silicon-controlled switch (SCS), etc.) and a FET so as to create a single integrated circuit device capable of quickly (e.g., within a few microseconds) turning on and turning off substantially large currents (e.g., tens of amperes or more). The exemplary FET-thyristor device 300 comprises a semiconductor substrate 301, which may be, for example, a P-type wafer, including a plurality of differently doped layers forming a sequence of alternating conductivity types (e.g., N-type or P-type). The substrate 301 may be formed of single-crystal silicon (e.g., having a <100> or <111> crystal orientation), although suitable alternative materials may also be used, such as, but not limited to, germanium (Ge), gallium arsenide (GaAs), etc. The doped layers may be formed by introducing selected impurities (e.g., boron, phosphorous, arsenic, etc.) into the substrate of a specified doping concentration (e.g., such as by ion implantation, diffusion, etc.), as will be known by those skilled in the art. The term “semiconductor layer” as may be used herein refers to any semiconductor material upon which and/or in which other materials may be formed.

The substrate 301 in the exemplary FET-thyristor device 300 comprises a first N-type semiconductor layer 302, which forms a cathode (K) of the device, and a first P-type semiconductor layer 304, which forms an anode (A) of the device. A second N-type semiconductor layer 306 is formed in the substrate 301 laterally adjacent to the first P-type layer 304. A second P-type semiconductor layer 308 is formed in the substrate 301 between and adjacent to the first and second N-type layers 302 and 306, respectively. Thus, at least a portion of the exemplary FET-thyristor device 300 preferably comprises a four-layer N—P—N—P sandwich structure resembling the SCR depicted in FIG. 2. With the N-type and P-type semiconductor layers arranged in this manner, three P—N junctions are formed in the FET-thyristor device 300, namely, junction J1, formed between second P-type semiconductor layer 308 and first N-type semiconductor layer 302, junction J2, formed between second P-type semiconductor layer 308 and second N-type semiconductor layer 306, and junction J3, formed between first P-type semiconductor layer 304 and second N-type semiconductor layer 306. The FET-thyristor device 300 includes a first gate contact (G1) for providing electrical connection to the second N-type semiconductor layer 306.

A first bias source 314 supplying a bias voltage, Baa, may be configured such that a negative (−) terminal of the bias source is connected to the cathode 302 and a positive (+) terminal of the bias source is connected to the anode 304 of the FET-thyristor device 300. A first switch, S1, may be connected in series with either the positive or negative terminal of the bias source 314 for selectively applying the bias voltage Baa across the FET-thyristor device 300. When the bias voltage Baa is applied to the FET-thyristor device 300, such as by closing switch S1, junctions J1 and J3 will become forward-biased and junction J2 will become reverse-biased. With junction J2 reverse-biased, substantially no current, other than perhaps leakage current, will flow through the FET-thyristor device 300 from the cathode 302 to the anode 304. By applying a positive voltage of sufficient amplitude to the gate contact G1, holes will be injected into N-type semiconductor layer 306. When the number of holes, which are minority carriers in the N-type material, overwhelms the number of electrons, which are majority carriers in the N-type material, the N-type semiconductor layer 306 will effectively behave as a P-type layer, thus forming an N—P—P—P layer device which is forward-biased. An anode current, Ia, will flow through the FET-thyristor device 300 which is limited primarily by an on-resistance of the device and a resistance of an external circuit to which the device is connected. Once the FET-thyristor device 300 begins conducting, the signal applied to gate contact G1 will have virtually no effect on the anode current Ia. Thus, the mechanism for turning on the FET-thyristor device 300 is similar to the mechanism for turning on the SCR previously described in conjunction with FIG. 2.

In order to precisely control the anode current Ia in the FET-thyristor device 300, without the need for external circuitry (e.g., commutation circuits, etc.), one or more N-type gate regions 310 are formed on upper and lower surfaces of the substrate 301, proximate (e.g., above and below) the second P-type semiconductor layer 308. For example, the N-type gate regions 310 may be formed as a ring at least partially surrounding the second P-type semiconductor layer 308. The N-type gate regions 310 are preferably doped with a higher impurity concentration than the N-type semiconductor layers 302 or 306, and are therefore designated as N+ regions. Additional P—N junctions will therefore be formed in the FET-thyristor device between the second P-type semiconductor layer 308 and each of the N+ gate regions 310. Second gate contacts, G2, are included for providing electrical connection to the N+ gate regions 310.

The portion of the FET-thyristor device 300 comprising first and second N-type semiconductor layers 302, 306, second P-type semiconductor layer 308, and N+ gate regions 310, functions in a manner similar to the FET device previously described in conjunction with FIG. 1. Specifically, first N-type semiconductor layer 302 may be viewed as a source region and second N-type semiconductor layer 306 may be viewed as a drain region, with N+ gate regions 310 functioning as a gate for controlling the current. When a positive bias voltage Baa is applied to the FET-thyristor device 300, electrons supplied by the first N-type semiconductor layer 302 (e.g., source) will be passed to the second N-type semiconductor layer 306 (e.g., drain), since a voltage gradient will be created between the first and second N-type semiconductor layers.

A second bias source 316 supplying a bias voltage, Vgg2, is preferably configured such that a positive (+) terminal of the second bias source is connected to the second gate contacts G2 and a negative (−) terminal of the second bias source is connected to the cathode 302 of the FET-thyristor device 300. In order to set the potential of the second P-type semiconductor layer 308 relative to the second gate contacts G2, an additional contact, G2′, is preferably provided which is connected to the cathode 302 of the FET-thyristor device 300. A second switch, S2, may be connected in series with either the positive or negative terminals of second bias source 316 for selectively applying bias voltage Vgg2 to the second gate contacts G2.

When the bias voltage Vgg2 of sufficient amplitude is applied to the second gate contacts G2 (e.g., by closing switch S2), the two P-N junctions between the second P-type semiconductor layer 308 and the N+ gate regions 310 will become reverse-biased. In accordance with the principles of FET device operation (described above), corresponding depletion regions 312 will be formed in the second P-type semiconductor layer 308 proximate the N+ gate regions 310. A depth of the depletion regions 312 will be a function of the magnitude of bias voltage Vgg2. Between the two depletion regions 312 a channel is formed in the second P-type semiconductor layer 308 having a width, W, which is proportional to the depth of the depletion regions. The deeper the depletion regions are, the smaller the channel width will be, and vice versa.

Once the FET-thyristor device 300 begins conducting, the anode current Ia in the device can be controlled primarily as a function of the channel width W. By varying the bias voltage Vgg2, the channel width can be varied accordingly, and thus the anode current Ia can be varied. This is an important benefit of the integrated FET-thyristor structure of the present invention. As the bias voltage Vgg2 applied to the device is increased, the channel will eventually become cut off and the anode current Ia will decrease substantially to zero. As in the case of the FET device described above in conjunction with FIG. 2, the voltage at which channel cutoff occurs in the FET-thyristor device 300 may be referred to as a pinch-off voltage, Vp, of the device. Thus, second gate contacts G2 can be used to turn off the current Ia in the FET-thyristor device 300, thereby eliminating the commutation circuitry required by conventional SCR devices or alternative power switching devices.

Since the FET-thyristor device 300 incorporates the beneficial characteristics of a FET, the FET-thyristor device exhibits gain and can therefore be used as an amplifier. A comparatively small change in gate current applied to second gate contacts G2 can influence a large change in anode current Ia. The change in anode current resulting from a change in gate current in G2 will be a function of the gain of the FET-thyristor device 300. Because a signal applied to the second gate contacts G2 can be used not only turn off the anode current Ia but also to modulate the anode current, the FET-thyristor device 300 may be employed, for example, as a modulator, demodulator, etc.

It is to be appreciated that the present invention is not limited to the exemplary FET-thyristor device 300 shown in FIG. 3. Rather, the present invention contemplates alternative arrangements for the FET-thyristor device. For example, additional layers of alternating P-type and N-type conductivities may be included, in accordance with other embodiments of the invention.

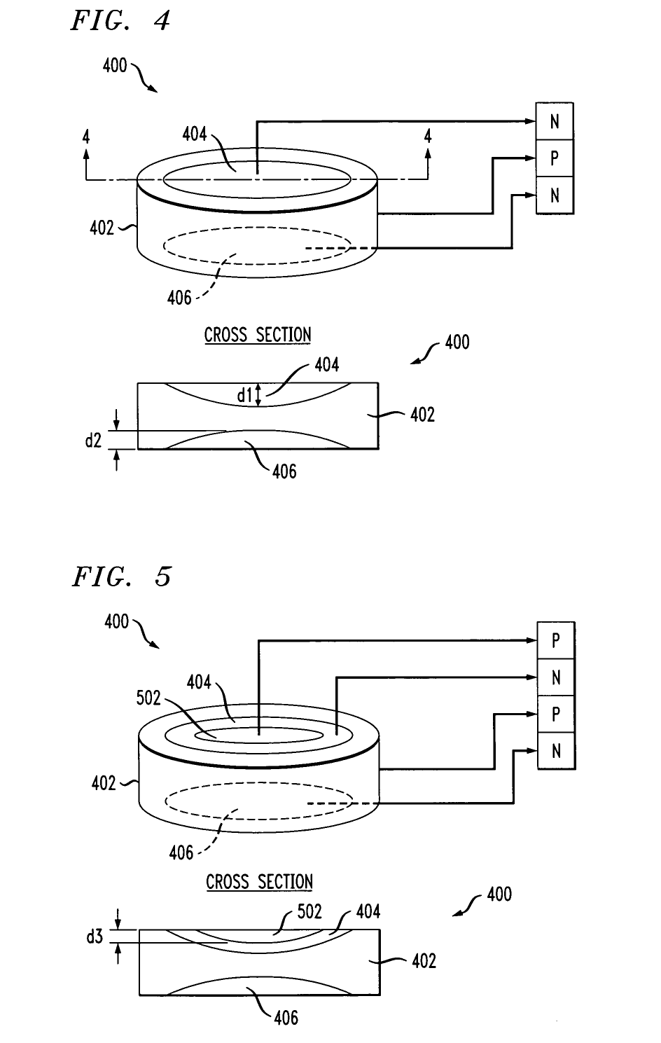

FIGS. 4-7 depict steps in an illustrative methodology which may be used in forming a FET-thyristor device of the type shown in FIG. 3, in accordance with one aspect of the present invention. The illustrative methodology will be described in the context of a conventional MOS-compatible semiconductor fabrication process technology. As previously stated, however, the invention is not limited to this or any particular methodology for fabricating the FET-thyristor device.

FIG. 4 depicts at least a portion of an exemplary semiconductor structure 400 in which the techniques of the present invention are implemented. An oblique view of the structure 400 is shown, with a corresponding cross-sectional view of the wafer taken along line 4-4. Preferably, a silicon wafer 402 is employed into which a P-type impurity or dopant (e.g., Boron) of a desired concentration level has been added, for example, using a standard epitaxy process, to form a P-type semiconductor wafer. One or more other semiconductor regions of the FET-thyristor device are subsequently formed in the P-type semiconductor wafer 402.

First and second N-type semiconductor regions 404 and 406, respectively, are formed in the P-type semiconductor wafer 402, such as, for example, using a standard diffusion process. In forming the first N-type semiconductor region 404, an N-type dopant (e.g., phosphorous, arsenic, etc.) may be diffused on a top surface of the wafer 402. Likewise, in forming the second N-type semiconductor region 406, an N-type dopant may be diffused on a bottom surface of the wafer 402. A depth, d1, of the first N-type semiconductor region 404 in the P-type semiconductor wafer 402, as measured from the top surface of the wafer toward a center of the wafer, is preferably greater than a depth, d2, of the second N-type semiconductor region 406 in the wafer, as measured from the bottom surface of the wafer toward the center of the wafer, since the first N-type semiconductor region must accommodate at least one additional P-type semiconductor region, as will be described below. The depths of the respective diffusion regions 404, 406 may be controlled, for example, by varying a temperature and/or time of the diffusion process, as will be known by those skilled in the art.

With reference to FIG. 5, a P-type semiconductor region 502 is preferably formed in the first N-type semiconductor region 404, such as, for example, using a standard diffusion process. The P-type semiconductor region 502 and the first N-type semiconductor region 404 are preferably arranged substantially concentric with respect to each other. In the forming the P-type semiconductor region 502, a P-type dopant (e.g., Boron) may be diffused on the top surface of the wafer 402. A depth, d3, of the P-type semiconductor region 502 in the first N-type semiconductor region 404 should be less than the depth d1 of the N-type semiconductor region so that the P-type semiconductor region 502 does not electrically contact the P-type wafer 402. If d3 was greater than d1, the respective P-N junctions formed between P-type wafer 402 and N-type semiconductor region 404 and between P-type semiconductor region 502 and N-type semiconductor region 404 would effectively be eliminated and the resulting FET-thyristor device would not function properly.

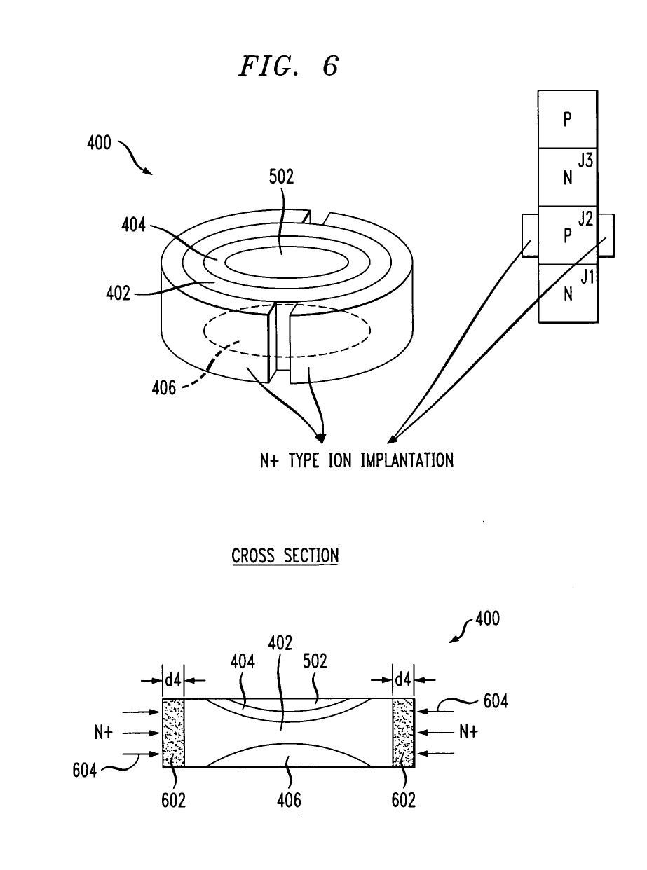

FIG. 6 illustrates an exemplary methodology for forming one or more N-type gate regions 602 in the wafer 402. The N-type gate regions 602 may be formed, for example, using a standard ion implantation process, wherein sides of the wafer 402 are ion implanted with an N+dopant 604 (e.g., Boron) to a suitable thickness, d4. The N+ dopant 604 is preferably implanted substantially around a circumference of the wafer 402. A direction of the ion implantation is preferably substantially perpendicular to an outer surface of the sides of the wafer 402, and is thus directed in a plane that is substantially parallel to a plane of the wafer (e.g., horizontal, as shown in the figure). The depth d4 of the N-type gate regions 602 is not critical, as long as the N-type gate regions do not make electrical contact with the N-type semiconductor region 404. The depth of the ion implantation can be controlled as a function of, for example, dopant dose (e.g., atoms per square centimeter), energy level (e.g., kilo electron-volt), and/or angle or implantation, as will be known by those skilled in the art.

The N+ gate regions 602 are shown in the figure as being split into two segments of a ring, with each gate segment having a separate gate electrode (G2) corresponding thereto. The two gate electrodes G2 are then electrically connected together. The N+ gate regions 602 need not be comprised of multiple segments of a ring. Rather, the present invention contemplates that the N+ gate regions 602 may be formed as a continuous cylindrical structure from which only a single gate electrode (G2) is drawn. Although N+ gate regions 602 may be formed using alternative methodologies (e.g., diffusion, etc.), ion implantation is preferred since it can be performed at a substantially lower temperature (e.g., about 25 degrees Celsius) compared to a diffusion process (e.g., about 800 to 1250 degrees Celsius). In this manner, forming the N+ gate regions 602 will not significantly alter the existing FET-thyristor structure.

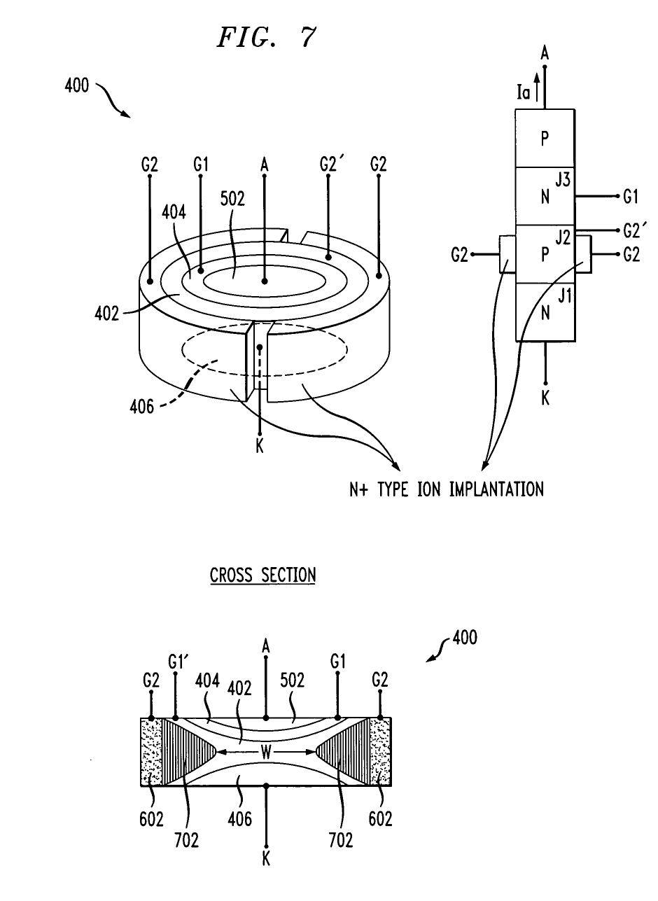

FIG. 7 depicts the completed FET-thyristor device, including an anode (A) contacting P-type semiconductor region 502, a cathode (K) contacting N-type semiconductor region 406, a first gate electrode (G1) contacting N-type semiconductor region 404, second gate electrodes (G2) contacting N-type gate regions 602, and a substrate electrode (G2′) connecting to the P-type semiconductor wafer 402. As previously explained, when the N+ gate regions 602 are reverse-biased, such as by applying a positive voltage potential between second gate electrodes G2 and substrate electrode G2′, depletion regions 702 will be established in the P-type wafer 402. The depletion regions 702 will form proximate (e.g., under) the respective N+ Gate regions 602.

A depth of the depletion regions 702 in the wafer 402, and thus a channel width, W, in the FET-thyristor device, will be primarily a function of the magnitude of the voltage between electrodes G2 and G2′. For example, as the voltage across the electrodes G2 and G2′ increases, the channel width W will decrease and the depth of depletion regions 702 will increase, as measured from the sides of P-type wafer 402 proximate the N+ gate regions 610 toward the center the of the wafer. As the voltage across electrodes G2 and G2′ is increased further, the channel width W will approach zero, at which point an anode current, Ia, in the FET-thyristor device will be substantially zero. In this manner, the anode current in the FET-thyristor device can be advantageously controlled, without the use of external commutation circuitry, as is required by conventional SCR devices.

At least a portion of the FET-thyristor device of the present invention may be implemented in an integrated circuit. In forming integrated circuits, a plurality of identical die is typically fabricated in a repeated pattern on a surface of a semiconductor wafer. Each die includes a device described herein, and may include other structures and/or circuits. The individual die are cut or diced from the wafer, then packaged as an integrated circuit. One skilled in the art would know how to dice wafers and package die to produce integrated circuits. Integrated circuits so manufactured are considered part of this invention.

Although illustrative embodiments of the present invention have been described herein with reference to the accompanying drawings, it is to be understood that the invention is not limited to those precise embodiments, and that various other changes and modifications may be made therein by one skilled in the art without departing from the scope of the appended claims.

What is claimed is:

1. An integrated field-effect transistor (FET)-thyristor device, comprising:
a semiconductor substrate of a first conductivity type;
a first semiconductor region of a second conductivity type formed in the substrate proximate an upper surface of the substrate;
a second semiconductor region of the second conductivity type formed in the substrate proximate a bottom surface of the substrate, the second semiconductor region being substantially vertically aligned with and spaced apart from the first semiconductor region;
a third semiconductor region of the first conductivity type formed in a portion of the first semiconductor region proximate the upper surface of the substrate; and
at least one gate region of the second conductivity type formed on a sidewall of the substrate and substantially surrounding at least a portion of each of the first, second and third semiconductor regions.

2. The device of claim 1, further comprising:
a first contact electrically connected to the second semiconductor region;
a second contact electrically connected to the third semiconductor region;
a first gate contact electrically connected to the first semiconductor region; and
a second gate contact electrically connected to the at least one gate region.

3. The device of claim 1, wherein the device is configured such that when a bias signal is applied between the at least one gate region and the substrate, at least one depletion region is formed in the substrate proximate the at least one gate region, a depth of the at least one depletion region in the substrate being controlled as a function of a magnitude of the applied bias signal.

4. The device of claim 1, wherein the first conductivity type is P-type and the second conductivity type is N-type.

5. The device of claim 1, wherein the second semiconductor region comprises a cathode of the device and the third semiconductor region comprises an anode of the device.

6. The device of claim 1, wherein the first and third semiconductor regions are arranged substantially concentric relative to one another.

7. The device of claim 1, wherein when the device is forward-biased and conducting a current, a magnitude of the current in the device is selectively controlled as a function of a gate signal applied to the second gate contact.

8. The device of claim 1, wherein a depth of the first semiconductor region in the substrate is greater than a depth of the second semiconductor region in the substrate.

9. The device of claim 1, wherein the at least one gate region comprises a plurality of gate regions formed on the sidewall of the substrate, each of the gate regions being electrically isolated from one another and forming respective segments of a ring substantially surrounding the first, second and third semiconductor regions.

10. The device of claim 1, wherein the at least one gate region comprises a continuous substantially cylindrical structure surrounding the first, second and third semiconductor regions.

11. An integrated field-effect transistor (FET)-thyristor device, comprising:
a semiconductor substrate having a plurality of differently doped layers, the plurality of differently doped layers including a multiple-layer sequence comprising:
a first doped layer of a first conductivity type;
a second doped layer of a second conductivity type formed laterally adjacent to the first doped layer;
a third doped layer of the first conductivity type formed laterally adjacent to the second doped layer; and
a fourth doped layer of the second conductivity type formed laterally adjacent to the third doped layer;
at least one gate region of the first conductivity type formed on an upper surface and a bottom surface of the semiconductor substrate, vertically adjacent to the second doped layer and electrically isolated from the first and third doped layers;
a first gate contact providing electrical connection to the third doped layer; and
at least a second gate contact providing electrical connection to the at least one gate region.

12. The device of claim 11, wherein the device is configured such that when a bias signal is applied between the second gate contact and the second doped layer, at least one depletion region is formed in the second doped layer proximate the at least one gate region, a depth of the at least one depletion region in the second doped layer being controlled as a function of a magnitude of the applied bias signal.

13. The device of claim 11, wherein first conductivity type is N-type and the second conductivity type is P-type.

14. The device of claim 11, wherein the first doped layer comprises a cathode of the device and the fourth doped layer comprises an anode of the device.

15. The device of claim 11, wherein when the device is forward-biased and conducting a current, a magnitude of the current in the device is selectively controlled as a function of a gate signal applied to the second gate contact.

16. The device of claim 11, wherein the at least one gate region is formed as at least a portion of a ring which substantially surrounds the second doped layer.

17. An integrated circuit comprising at least one integrated field-effect transistor (FET)-thyristor device, the at least one FET-thyristor device comprising:
a semiconductor substrate of a first conductivity type;
a first semiconductor region of a second conductivity type formed in the substrate proximate an upper surface of the substrate;
a second semiconductor region of the second conductivity type formed in the substrate proximate a bottom surface of the substrate, the second semiconductor region being substantially vertically aligned with and spaced apart from the first semiconductor region;
a third semiconductor region of the first conductivity type formed in a portion of the first semiconductor region proximate the upper surface of the substrate; and
at least one gate region of the second conductivity type formed on a sidewall of the substrate substantially surrounding at least a portion of each of the first, second and third semiconductor regions.

18. The integrated circuit of claim 17, wherein the at least one the at least one FET-thyristor device further comprises:
a first contact electrically connected to the second semiconductor region;
a second contact electrically connected to the third semiconductor region;
a first gate contact electrically connected to the first semiconductor region; and
a second gate contact electrically connected to the at least one gate region.

19. The integrated circuit of claim 18, wherein the at least one FET-thyristor device is configured such that when a bias signal is applied between the second gate contact and the substrate, at least one depletion region is formed in the substrate proximate the at least one gate region, a depth of the at least one depletion region in the substrate being controlled as a function of a magnitude of the applied bias signal.

20. A method of forming an integrated field-effect transistor (FET)-thyristor device, the method comprising the steps of:
forming a first semiconductor region of a first conductivity type formed in a semiconductor substrate of a second conductivity type proximate an upper surface of the substrate;
forming a second semiconductor region of the first conductivity type in the substrate proximate a bottom surface of the substrate, the second semiconductor region being substantially vertically aligned with and spaced apart from the first semiconductor region;
forming a third semiconductor region of the second conductivity type in a portion of the first semiconductor region proximate the upper surface of the substrate; and
forming at least one gate region of the first conductivity type on a sidewall of the substrate substantially surrounding at least a portion of each of the first, second and third semiconductor regions.
